(19) United States
(12) Patent Application Publication
(10) Pub. No.: US 2013/0229777 A1
(43) Pub. Date: Sep. 5, 2013

(54) CHIP ARRANGEMENTS AND METHODS FOR FORMING A CHIP ARRANGEMENT

(71) Applicants: Ralf Otremba, Kaufbeuren (DE); Marco Seibt, Villach (AT)

(72) Inventors: Ralf Otremba, Kaufbeuren (DE); Marco Seibt, Villach (AT)

(73) Assignee: INFINEON TECHNOLOGIES AG, Neubiberg (DE)

(21) Appl. No.: 13/409,260

(22) Filed: Mar. 1, 2012

(51) Int. Cl. H05K 7/06; H05K 3/30

(52) U.S. Cl. 361/783; 361/760; 29/841

(57) ABSTRACT

A chip arrangement is provided: the chip arrangement including: a carrier; a chip disposed over the carrier; a ceramic layer formed over the chip and on at least a portion of the carrier; wherein the chip is surrounded by the carrier and the ceramic layer.

### TECHNICAL FIELD

Various embodiments relate generally to chip arrangements and methods for forming a chip arrangement.

### BACKGROUND

Chip packages, e.g. TO220-3, e.g. TO224-3, usually include one or more active components arranged within discrete housings. Normal chip embedding technologies may be only partially electrically insulating, and the electrically insulating material may include partially or fully, organic materials, and may therefore not be suitable for high temperature, e.g. higher than 200° C. applications. The active components may be arranged for applications such as an alternating current or direct current application. The chip packages may be unsuitable, e.g. unreliable, for high temperature applications, i.e. temperatures higher than about 200° C., as existing interface areas may be subject to delamination and/or degradation. Mold compound materials, e.g. the epoxy used in mold compounds may be stable up to about 150° C., but may undergo degradation and/or delamination at temperatures higher than about 150° C. Solder materials may be stable up to about 200° C., but may undergo Kirkendall-Voiding through interdiffusion with the lead frame material and/or exhibit peeling, at temperatures higher than about 200° C. Therefore, areas subject to reliability problems including delamination and/or degradation at higher temperatures may include for example, the mold compound-lead frame interface and/or the lead frame-solder interface, and/or the chip-wire bond interface.

### SUMMARY

Various embodiments provide a chip arrangement, including: a carrier; a chip disposed over the carrier; a ceramic layer formed over the chip and on at least a portion of the carrier; wherein the chip is surrounded by the carrier and the ceramic layer.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1 shows a method for forming a chip arrangement according to an embodiment;

FIG. 2 shows a graph illustrating physical properties of Silicon Carbide;

FIG. 3 shows a chip arrangement according to an embodiment;

FIG. 4 shows a method for forming a chip arrangement according to an embodiment;

FIGS. 5A to 5D show methods for forming a chip arrangement according to various embodiments;

FIG. 6 shows part of a chip arrangement according to an embodiment;

FIG. 7A shows a chip arrangement according to an embodiment;

FIG. 7B shows a chip arrangement according to an embodiment;

FIG. 8 shows a chip arrangement according to an embodiment.

### DETAILED DESCRIPTION

The following detailed description refers to the accompanying drawings that show, by way of illustration, specific details and embodiments in which the invention may be practiced.

The word “exemplary” is used herein to mean “serving as an example, instance, or illustration”. Any embodiment or design described herein as “exemplary” is not necessarily to be construed as preferred or advantageous over other embodiments or designs.

The word “over” used with regards to a deposited material formed “over” a side or surface, may be used herein to mean that the deposited material may be formed “directly on”, e.g. in direct contact with, the implied side or surface. The word “over” used with regards to a deposited material formed “over” a side or surface, may be used herein to mean that the deposited material may be formed “indirectly on” the implied side or surface with one or more additional layers being arranged between the implied side or surface and the deposited material.

Various embodiments provide a ceramic embedding material for a chip which may be configured to withstand temperatures greater than 200° C. and possibly even higher than 500° C.

Various embodiments provide a ceramic embedding material for a chip, wherein the power density of active devices, e.g. power semiconductor devices, e.g. logic transistors, and passive components, e.g. capacitors and inductors, used in high voltage applications, e.g. AC/DC converters, may be significantly increased, in comparison to the usual silicon based chips.

Various embodiments provide ceramic embedding material for a chip, wherein interface and material limits for power semiconductor components, may be eliminated, reduced and/or prevented. In other words, chip housings or chip packaging materials may no longer be a limiting factor in the operating temperatures of the chips; instead the operating temperatures will depend on the chips themselves.

Various embodiments provide chip packages for chip technologies with bandgaps of, e.g. about 2 eV, which are larger than the bandgap of Silicon, e.g. about 1 eV, wherein the chip technologies may be operated at higher temperatures, e.g. higher than >200° C.

Various embodiments provide semiconductor chip packages including a ceramic embedding material, wherein one or more chips including a power semiconductor component and/or a passive component may be embedded in the ceramic embedding material, and wherein the one or more chips may be rewired by electrically conductive, e.g. metallic, interconnects.

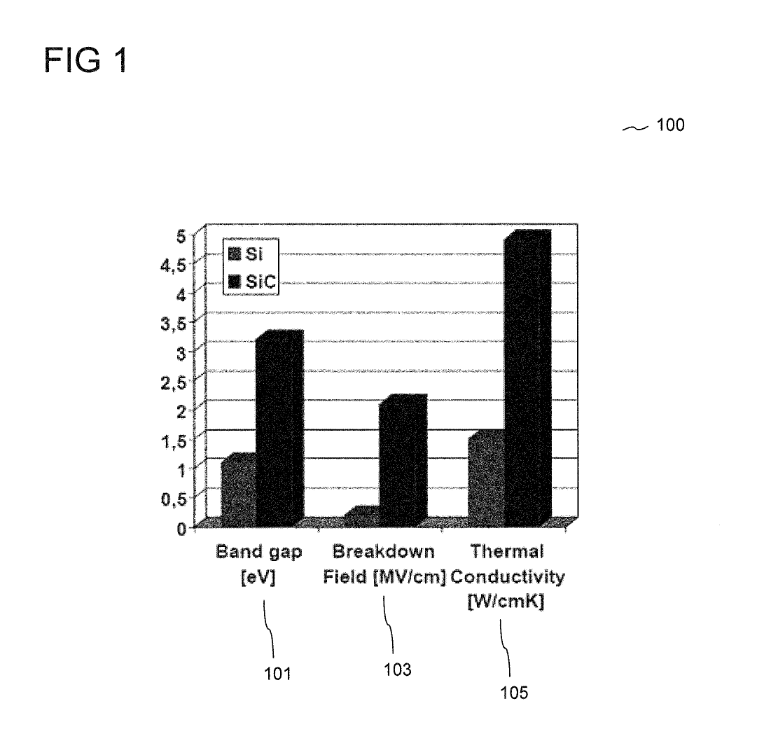

Various embodiments provide chip packages for power semiconductor chips, the power semiconductor chips including silicon carbide, gallium nitride, aluminum nitride. These power semiconductor chips may have different physical properties compared to conventional silicon chips as shown in FIG. 1.

FIG. 1 shows graph 100 illustrating physical properties of Silicon Carbide. Silicon carbide may be chemically stable, mechanically resilient (hard), radiation resilient (hard), may have excellent stability towards cosmic radiation, and may be non-toxic. Furthermore, silicon carbide may have high thermal stability even for temperatures higher than 500° C., e.g. operation temperatures, Tⱼ, even up to 250° C. may not be a problem. Silicon carbide may have a bandgap 101 of about 3 eV, which may be larger than the bandgap of silicon, e.g. larger than 1 eV. Silicon carbide may further exhibit larger breakdown field MV/cm 103, and larger thermal conductivity W/cmK 105.

Semiconductor chips, such as power semiconductor chips and possibly even logic semiconductor chips, which are able to operate at high temperatures, e.g. higher than 200° C., may require a chip arrangement as described according to various embodiments to withstand the high operating temperatures without degradation and/or delamination.

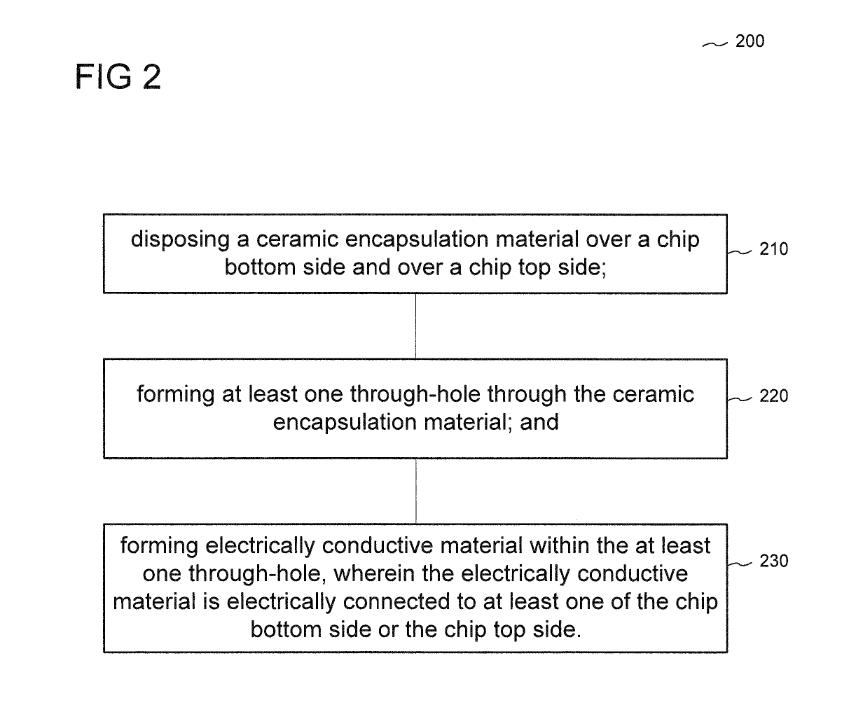

FIG. 2 shows method 200 for forming a chip arrangement according to an embodiment. Method 200 may include

disposing a ceramic encapsulation material over a chip bottom side and over a chip top side (210);

forming at least one through-hole through the ceramic encapsulation material (220); and

forming electrically conductive material within the at least one through-hole, wherein the electrically conductive material is electrically connected to at least one of the chip bottom side or the chip top side (230).

Method 200 may further include disposing the ceramic encapsulation material over one or more chip lateral sides wherein the ceramic encapsulation material surrounds the chip; and subsequently performing a sintering process on at least one of the carrier and the ceramic layer.

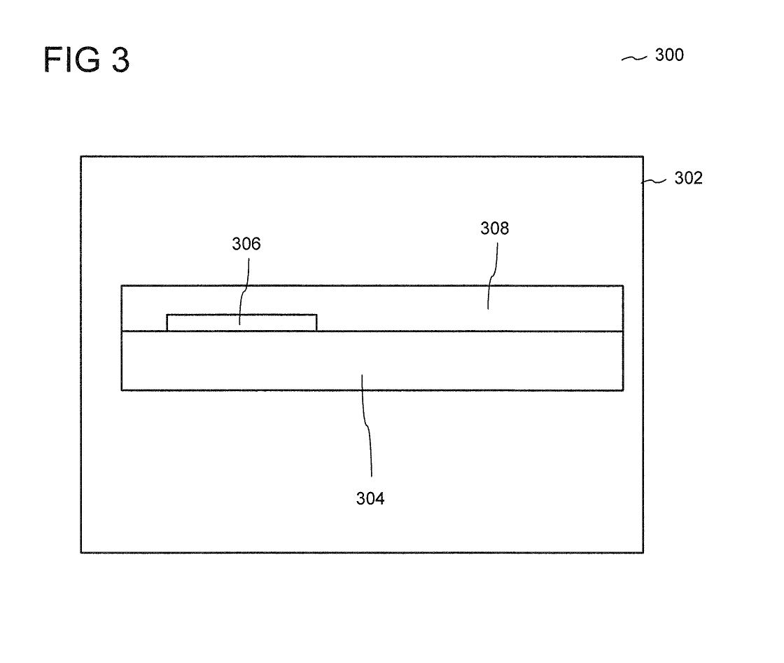

FIG. 3 shows chip arrangement 302 according to an embodiment. Chip arrangement 302 may include carrier 304; chip 306, e.g. a semiconductor die, disposed over carrier 304; ceramic layer 308 formed over chip 306 and on at least a portion of carrier 304; wherein chip 306 may be surrounded by carrier 304 and ceramic layer 308.

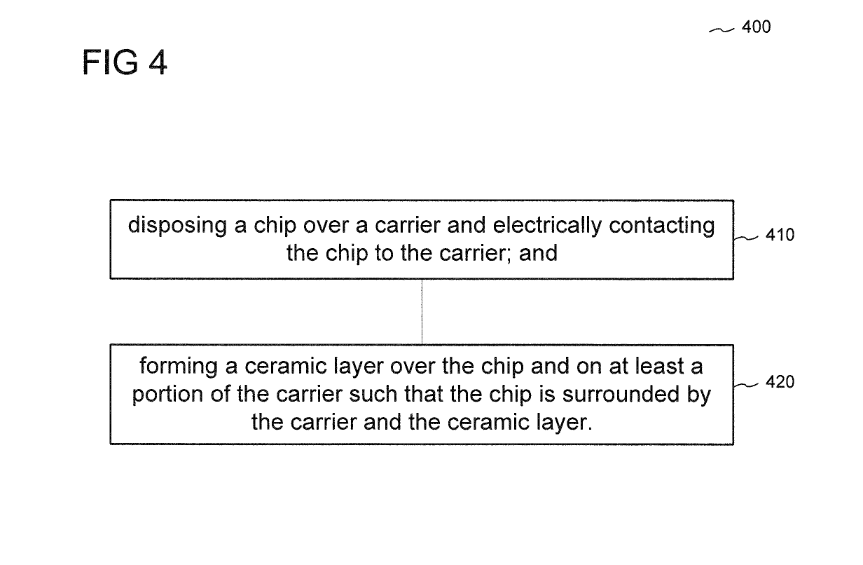

FIG. 4 shows method 400 for forming a chip arrangement according to an embodiment. Method 400 may include:

disposing a chip over a carrier and electrically contacting the chip to the carrier (410); and

forming a ceramic layer over the chip and on at least a portion of the carrier such that the chip is surrounded by the carrier and the ceramic layer (420).

Method 400 may further include subsequently performing a sintering process on at least one of the carrier and the ceramic layer.

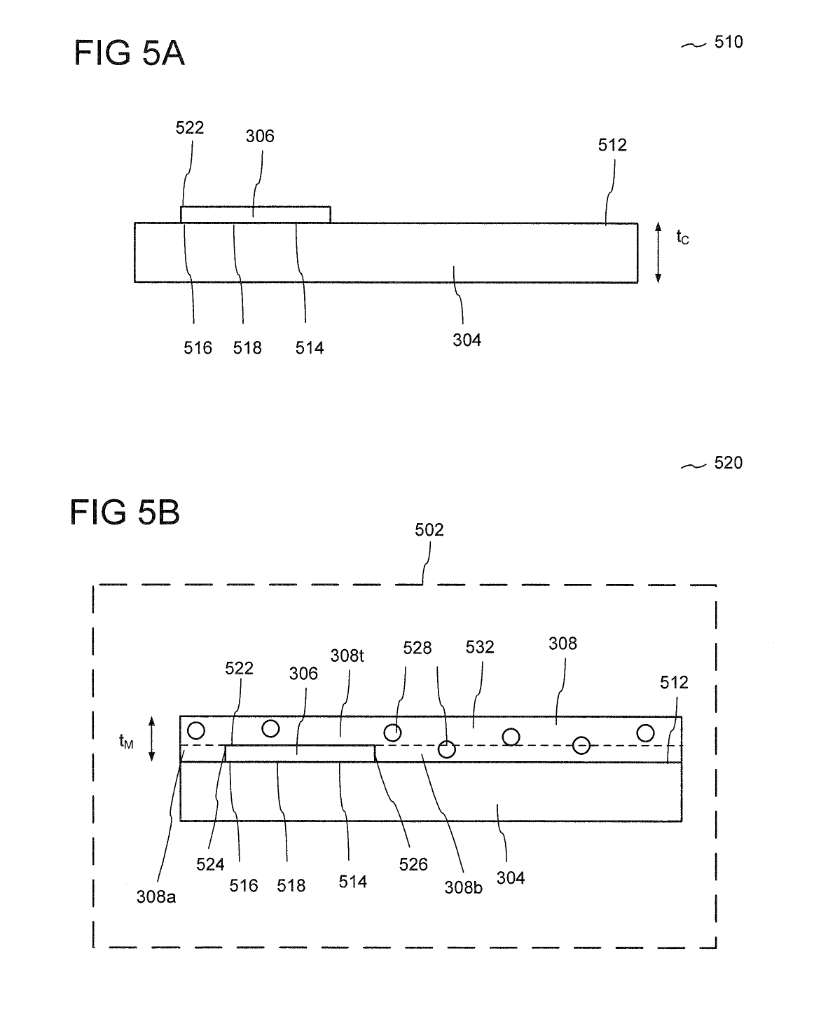

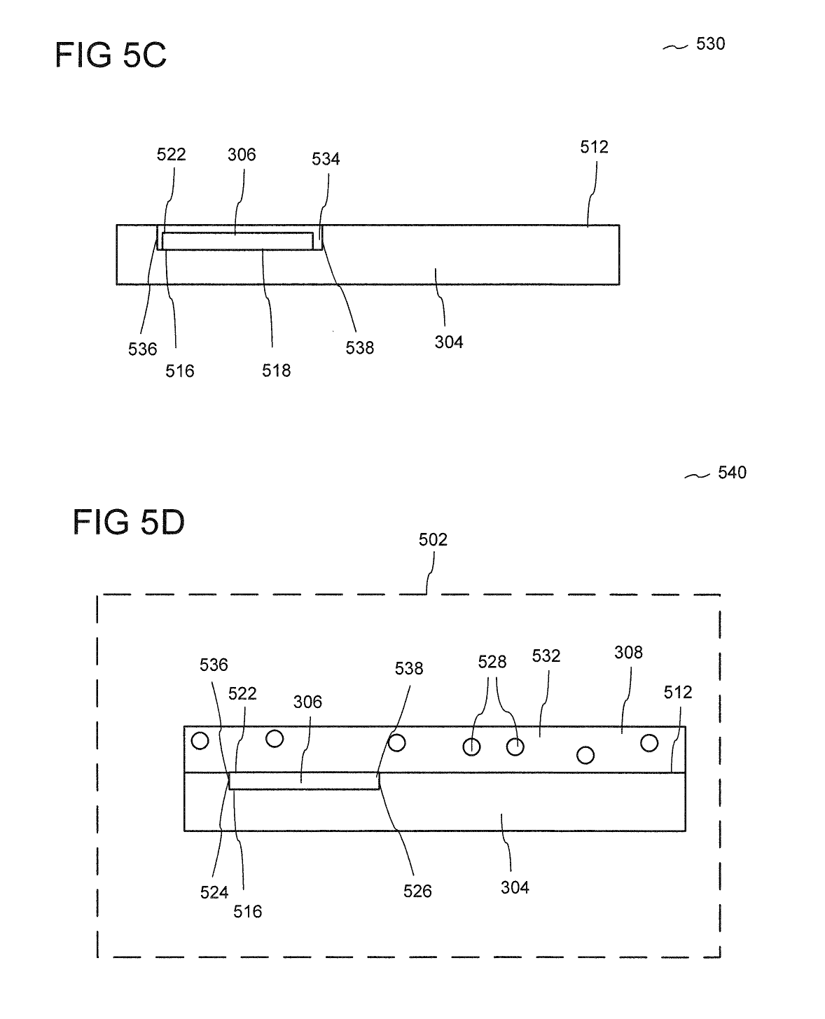

FIGS. 5A and 5B show a method for forming a chip arrangement, e.g. chip arrangement 302, chip arrangement 502 according to an embodiment.

In FIG. 5A, chip 306, e.g. a semiconductor chip, e.g. a semiconductor die may be disposed over carrier 304. Optionally, chip 306 may be adhered to carrier 304 via adhesive medium 518.

Chip 306 may have a thickness (bottom side to top side) ranging from about 5 μm to about 500 μm, e.g. from about 10 μm to about 350 μm, e.g. from about 50 μm to about 250 μm.

According to an embodiment, carrier 304 may include a lead frame carrier. Carrier 304, e.g. the lead frame, may include an electrically conductive material. Carrier 304, e.g. the lead frame, may include at least one from the following group of materials, the group of materials consisting of: copper, nickel, iron, copper alloy, nickel alloy, iron alloy.

According to another embodiment, carrier 304 may include an electrically conductive layer such as an electrically conductive sheet and/or an electrically conductive plate. Carrier 304, e.g. the electrically conductive layer, may include an electrically conductive material, the electrically conductive material including at least one material from the following group of materials, the group consisting of: copper, aluminum, silver, tin, gold, zinc, nickel, palladium, platinum.

According to another embodiment, carrier 304 may include an electrically insulating material, e.g. a ceramic material.

According to various embodiments, chip 306 may include a power semiconductor chip, e.g. devices capable of carrying a voltage of up to approximately 6000 V. For example, chip 306 may include a power semiconductor chip carrying a voltage ranging from about 150 V to about 6000 V, e.g, about 200 V to about 3000 V, e.g. about 250 V to about 1000 V. The power semiconductor chip may include at least one power semiconductor device from the group of power semiconductor devices, the group consisting of: a power transistor, a power MOS transistor, a power bipolar transistor, a power field effect transistor, a power insulated gate bipolar transistor, a thyristor, a MOS controlled thyristors, a silicon controlled rectifier, a power schottky diode, a silicon carbide diode, a gallium nitride device, an aluminum nitride device.

According to various embodiments, chip 306 may include a semiconductor logic chip. The semiconductor logic chip may include at least one semiconductor logic device from the group of semiconductor logic devices, the group consisting of: an application specific integrated circuit ASIC, a driver, a controller, a sensor. It may be understood that a semiconductor logic chip i.e. a logic integrated circuit chip, may include a low power semiconductor device, e.g. devices capable of carrying up to 100 V to 150 V and/or devices capable of carrying up to 6000 V with lower current.

According to an embodiment, wherein chip 306 may include a power semiconductor chip, and wherein carrier 304 may include an electrically conductive material, e.g. a lead frame and/or an electrically conductive layer, then chip 306 may be electrically connected to carrier side 512, e.g. a chip carrier top side 512, via at least one contact pad 514 formed over chip bottom side 516. Contact pad 514 may include a first source/drain contact. Chip 306 may be electrically connected to carrier 304 via electrically conductive adhesive medium 518. Electrically conductive adhesive medium 518 may include at least one from the following group of materials, the group consisting of: a solder, a soft solder, a diffusion solder, a paste, a nanopaste, an adhesive, an electrically conductive adhesive, a thermally conductive adhesive. Electrically conductive adhesive medium 518 may include at least one from the following group of elements, the group of elements consisting of: Ag, Zn, Sn, Pb, Bi, In, Cu, Au.

Chip 306 may be formed directly on carrier 404. In other words, no other layers may be arranged between first chip 306 and carrier 304, apart from electrically conductive adhesive medium 518 which adheres first chip 306 to carrier 304.

Electrically conductive adhesive medium 518 may be configured to adhere chip bottom side 516 to carrier top side 512. Electrically conductive adhesive medium 518 may be configured to adhere at least one contact pad 514 formed on chip bottom side 516 to carrier top side 512.

Chip 306 may include chip top side 522 wherein first chip top side 522 may face a direction opposite to the direction that chip bottom side 516 faces.

As used herein, chip sides may be referred to throughout the text as follows. Top side may also be referred to as a “first side”, “front side” or “upper side” of the chip. The terms “top side”, “first side”, “front side” or “upper side” may be used interchangeably hereinafter. Bottom side may also be referred to as “second side” or “back side” of the chip. The terms “second side”, “back side”, or “bottom side” may be used interchangeably hereinafter.

As used herein with respect to semiconductor power devices e.g. chip 306, the terms “top side”, “first side”, “front side” or “upper side” may be understood to refer to the side of the chip wherein a gate region and at least one first source/drain region may be formed. The terms “second side”, “back side”, or “bottom side” may be understood to refer to the side of the chip wherein a second source/drain region may be formed. Therefore, a semiconductor power transistor may support a vertical current flow through the chip, e.g. between chip top side 522 and chip bottom side 516.

According to an embodiment, wherein chip 306 may include a lower power logic semiconductor chip, and carrier 304 may include an electrically conductive material, e.g. a lead frame or an electrically conductive layer, then chip bottom side 516 may be adhered to chip carrier 304 by electrically insulating adhesive medium 518. Therefore, chip 306 may be electrically insulated from carrier 304 by electrically insulating adhesive medium 518. Electrically insulating adhesive medium may include at least one from the following group of materials, the group consisting of: an adhesive, an electrically insulating adhesive, an epoxy, a glue, a paste, an adhesive foil, an electrically insulating wafer backside coating.

As used herein with respect to lower power semiconductor logic devices, e.g. chip 305, the terms “top side”, “first side”, “front side” or “upper side” may be understood to refer to the side of the chip which carries one or more contact pads, or electrical contacts, wherein bonding pads or electrical connects may be attached; or wherein it is the side of the chip which may be mostly covered by metallization layers. The terms “second side”, “back side”, or “bottom side” may be understood to refer to the side of the chip which may be free from metallization or contact pads or electrical contacts.

According to various embodiments, carrier 304 may not include an electrically conductive material, but a ceramic material, and chip 306 may include a semiconductor logic chip or a power semiconductor chip. Chip 306 may be disposed over carrier 304. Chip 306 may optionally, but not necessarily, be adhered to carrier 304 via adhesive medium 518. Adhesive medium 518 may include at least one from the following group of materials, the group consisting of: an adhesive, an electrically insulating adhesive, an epoxy, a glue, a paste, an adhesive foil, an electrically insulating wafer backside coating. Chip 306 may optionally be formed directly on carrier 304. In other words, no other layers may be arranged between first chip 306 and carrier 304, apart from electrically conductive adhesive medium 518 and/or electrically insulating adhesive medium 518 which adheres first chip 306 to carrier 304.

Electrically conductive adhesive medium 518 and/or electrically insulating adhesive medium 518 may be configured to adhere chip bottom side 516 to carrier top side 512. Electrically conductive adhesive medium 518 and/or adhesive medium 518 may be configured to adhere at least one contact pad 514 formed on chip bottom side 516 to carrier top side 512. In the case wherein chip 306 does not have at least one contact pad 514 formed on chip bottom side 516, e.g. in semiconductor logic devices, adhesive medium may optionally adhere chip bottom side 516 to carrier top side 512.

Chip 306 may include chip top side 522 wherein first chip top side 522 may face a direction opposite to the direction that chip bottom side 516 faces.

It may be understood that according to various embodiments, carrier 304 may include an electrically conductive sheet and/or layer wherein chip 306 may be disposed over carrier 304 and/or adhered to the carrier. It may be understood that according to various other embodiments, carrier 304 may include a deposited electrically conductive material formed over chip bottom side 516. For example, carrier 304 may be deposited by at least one of galvanic deposition, electrochemical deposition, chemical vapor deposition, plasma vapor deposition.

It may be understood that according to various other embodiments, carrier 304 may include a ceramic sheet and/or layer wherein chip 306 may be disposed over carrier 304 and/or adhered to the carrier. Carrier 304 may, for example, include one or more ceramic sheets, which may be used in low temperature cobalt fired ceramic LTCC applications. Carrier 304 may, for example, include one or more ceramic sheets, formed in stacked arrangement, e.g. one over the other. The one or more ceramic sheets may optionally be pre-sintered. The one or more ceramic sheets may or may not include indistinguishable boundaries between each ceramic sheet. Alternatively, the one or more ceramic sheets may be sintered during a subsequent sintering process described hereinafter. Each ceramic sheet may include a thickness ranging from about 0.01 mm to about 10 mm, e.g. about 0.1 mm to about 5 mm, e.g. about 0.1 mm to about 1 mm. Carrier 304 may have a thickness t_{C} ranging from about 0.01 mm to about 10 mm, e.g. about 0.1 mm to about 5 mm, e.g. about 0.1 mm to about 1 mm.

According to other embodiments, carrier 304 may be deposited by plasma dust and/or thermal spraying.

In FIG. 5B, ceramic layer 308 may be formed over chip 306 and on at least a portion of carrier 304 and chip 306 may be surrounded by carrier 304 and ceramic layer 308.

Ceramic layer 308 may be formed over chip 306, wherein ceramic layer 308 may at least partially surround chip 306. Ceramic layer 308 may have a thickness t_{M} ranging from about 0.01 mm to about 10 mm, e.g. about 0.1 mm to about 5 mm, e.g. about 0.1 mm to about 1 mm.

As described above, according to an embodiment, chip arrangement 502 may include carrier 304 and chip 306 may be disposed over and electrically contacted to carrier 304 if carrier 304 includes an electrically conductive material.

According to an embodiment, chip arrangement 502 may include carrier 304 and chip 306 may be disposed over and/or adhered to carrier 304, if carrier 304 includes a ceramic material, e.g. an electrically insulating ceramic material.

Ceramic layer 308 may be formed over and at least partially surrounding chip 306. Ceramic layer 308 may be formed over carrier 304 and over one or more chip lateral sides 524, 526. Ceramic layer 308 may be formed over, e.g. directly on, chip top side 522. Ceramic layer 308 may be formed over, e.g. directly on, one or more chip lateral sides 524, 526, Ceramic layer 308 may be formed over, e.g. directly on, carrier 304.

Carrier 304 and ceramic layer 308 may include the same or different materials. Carrier 304 and ceramic layer 308 may be arranged to surround chip 306 in a single process. According to an embodiment, at least one of carrier 304 and ceramic layer 308 may include an electrically insulating material. At least one of carrier 304 and ceramic layer 308 may include a thermally conductive material. At least one of carrier 304 and ceramic layer 308 may exhibit electrically insulating and thermally conducting properties. At least one of carrier 304 and ceramic layer 308 may include at least one material from the following group of materials, the group of materials consisting of: calcium oxide, aluminum oxide, silicon oxide, aluminum nitride, and zirconium oxide, boron nitride, a metal oxide, a metal nitride. At least one of carrier 304 and ceramic layer 308 may include one or more structures 528, one or more structures including: particles, nanoparticles, microparticles, fibers, microfibers, nanofibers, nanostructures, microstructures. One or more structures 528 may include at least one material from the following group of materials, the group of materials consisting of: calcium oxide, aluminum oxide, silicon oxide, aluminum nitride, and zirconium oxide, boron nitride, a metal oxide, a metal nitride. Each of one or more structures 528 may have a size ranging from about 1 μm to about 1 mm, e.g. about 5 μm to about 500 μm [0056], e.g. about 10 μm to about 100 μm. At least one of carrier 304 and ceramic layer 308 may each include a composite material including embedding portion 532 and filler portion 528. Embedding portion 532 may include, e.g. a matrix, e.g. a polymer matrix. Filler portion 528 may include one or more structures 528 which may be embedded in embedding portion 532. Embedding portion 532 may include at least one material from the following group of materials, the group of materials consisting of: epoxy, polyimide, duroplast, polyacrylate; and filler portion 528 may include one or more structures including at least one material from the following group of materials, the group of materials consisting of: calcium oxide, aluminum oxide, silicon oxide, aluminum nitride, and zirconium oxide, boron nitride, a metal oxide, a metal nitride.

It may be understood that carrier 304 may surround chip bottom side 516, and ceramic layer 308 may surround chip top side 522 and one or more lateral sides 524, 526 of chip 306.

According to an embodiment, carrier 304 may include a ceramic sheet, e.g. for LTCC as described above. Ceramic layer 308 may include ceramic layer first portion 308t which may be formed over chip top side 522. Ceramic layer 308 may further include ceramic layer first lateral portion 308a and ceramic layer second lateral portion 308b. Ceramic layer first lateral portion 308a may be formed over one lateral side 524 of chip 306. Ceramic layer second lateral portion 308b may be formed over another lateral side 526 of chip 306. Ceramic layer first lateral portion 308a and ceramic layer second lateral portion 308b may each be directly adjacent ceramic layer first portion 308t and carrier 304. In a subsequent sintering step, ceramic layer first lateral portion 308a and ceramic layer second lateral portion 308b may be joined, e.g. substantially seamlessly joined, directly to ceramic layer first portion 308t and carrier 304. Carrier 304 may surround chip bottom side 516, and ceramic layer 308 may surround chip top side 522 and one or more lateral sides 524, 526 of chip 306. Alternatively, ceramic layer 308 may be deposited by plasma dust and/or thermal spraying.

According to various embodiments, as shown in FIG. 5C, carrier 304 may include cavity 534 formed in carrier 304. Chip 306 may be disposed within cavity 534. Therefore, chip 306 may be disposed over carrier 304 within cavity 534. Adhesive medium 518 may be used to adhere chip bottom side 516 to carrier 304 within cavity 534. However, adhesive medium 518 may not be necessary, as a subsequent sintering process carried out after chip 306 is disposed over carrier 304, may adhere chip 306 directly to carrier 304. Therefore, low-temperature conventional materials, such as adhesive medium 518 may be eliminated.

In FIG. 5D, ceramic layer 308 may be formed over chip 306 and on at least a portion of carrier 304; wherein chip 306 may be surrounded by carrier 304 and ceramic layer 308. In this embodiment, ceramic layer 308 may be formed over, e.g. may surround chip top side 522 and carrier 304 may surround chip bottom side 516 and one or more lateral sides 524, 526 of chip 306. For example, ceramic layer 308 may be formed directly on chip top side 522 and carrier 304 may be formed directly on chip bottom side 516 and directly on one or more lateral sides 524, 526 of chip 306. One or more cavity sidewalls 536, 538 may be formed over, e.g. directly on, one or more lateral sides 524, 526 of chip 306. After chip 306 may be disposed over carrier 304, e.g. either over carrier top side 512 or within cavity 534, a sintering process may be carried out. The sintering process may include heating the package to a temperature ranging from about 200° C. to about 2000° C., e.g. about 300° C. to about 1750° C., e.g. about 500° C. to about 1500° C. As a result of the sintering process, carrier 304 may be adhered to chip 306. For example, carrier 304 may be formed directly on chip bottom side 516. Furthermore, ceramic layer 308 may be adhered to chip 306. For example, ceramic layer 308 may be formed directly on chip top side 522. Furthermore, at least one of ceramic layer 308 and carrier 304 may be adhered to chip 306. For example, at least one of ceramic layer 308 and carrier 304 may be formed directly on chip lateral sides 524, 526. Ceramic layer 308 may be joined seamlessly to carrier 304.

According to an embodiment, chip arrangement 502 may be understood to include a chip package, including: carrier 304; power semiconductor chip 306 disposed over carrier 304; an encapsulation material 308 formed over and at least partially surrounding the power semiconductor chip 306, wherein the encapsulation material 308 includes a plurality of ceramic structures 528 embedded in a filler material 532. Ceramic structures 528 may include one or more structures 528 already described above.

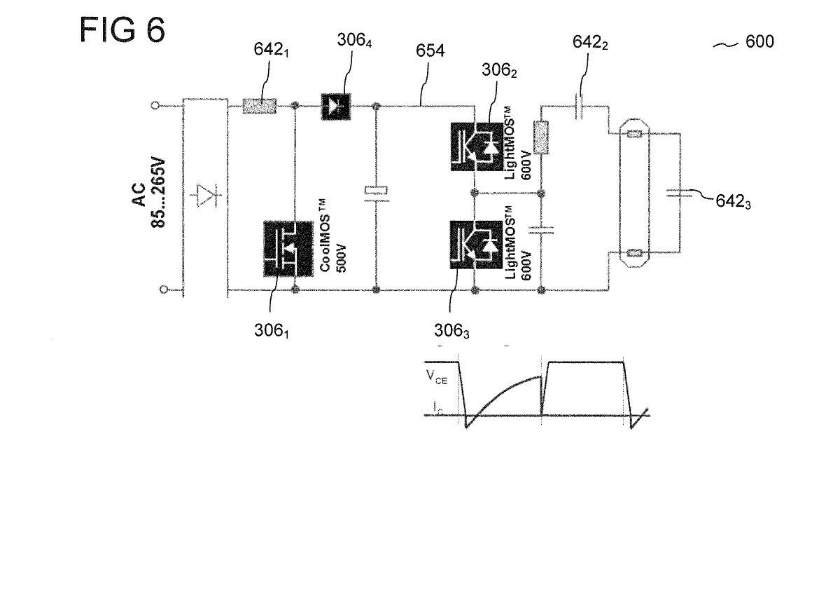

According to an embodiment, chip 306 may be part of a chip arrangement, e.g. chip 306 may form part of a power semiconductor circuit, e.g. a half-bridge circuit, e.g. a lamp ballast with a half-bridge architecture. FIG. 6 shows a diagram of part of a chip arrangement according to an embodiment. FIG. 6 shows a diagram of circuit 600, which may include a power semiconductor circuit including a lamp ballast with half-bridge architecture. Circuit 600 may include one or more chips 306. For example, circuit 600 may include one or more power semiconductor chip 306₁, 306₂, 306₃. Chip 306₁ may include a power semiconductor CoolMOS 500V chip. Chips 306₂, 306₃ may each include a power semiconductor LightMOS 600 V chip. Circuit 600 may include active components e.g. including chip 306₄, which may include a diode. Circuit 600 may include active components, for example at least one power semiconductor chip, e.g. chips 306₂, 306₃ electrically connected in a half bridge arrangement, wherein circuit 600 may further include other electronic components 642₁, 642₂, 642₃, e.g. passive components such as resistors and/or capacitors and/or inductors. As shown in the diagram of circuit 600, one or more chips 306₁, 306₂, 306₃, 306₄, may be electrically connected to each other, and/or to one or more other electronic components 642₁, 642₂, 642₃ via one or more electrical interconnects 654. It may be understood that one or more chips 306₁, 306₂, 306₃, 306₄, and/or one or more other electronic components 642₁, 642₂, 642₃ may be embedded in, e.g. surrounded by, at least one of carrier 304 and ceramic layer 308 as described above. Each individually ceramically embedded chip 306 and/or each individually ceramically embedded electronic component 642 may be joined to each other by a sintering process which may join the individual ceramic packages together.

Power semiconductor circuits, such as power semiconductor circuit 600 may operate at significantly increased power density in comparison to the usual silicon based chips, due to the provision of ceramic layer 308 as an embedding material for chip 306. In other words, the power circuits need no longer be limited by the degradation and/or delamination of the packaging materials. Furthermore, instead of only being arranged over a ceramic layer 308, active devices in circuit 600, e.g. one or more chips and/or diodes 306₁, 306₂, 306₃, 306₄, may instead be embedded in ceramic layer 308. As a result of chip embedding in ceramic layer 308, three-dimensional cooling of the active electronic components is possible, wherein furthermore, operations temperatures may be greatly increased, as the ceramic embedding material from housing may exhibit high temperature stability, e.g. much higher than 500° C., which may be used for new chip technologies. Ceramic layer 308 may be produced by low temperature co-fired ceramic LTCC production. The production of active components 306 and/or active modules, e.g. power and/or logic chips 306, may be carried out in parallel with electronic components 642, e.g. passive components. In other words the chip 306 and and/or electronic component 642, which may include, e.g. passive elements, may similarly be sintered within ceramic material 308 and/or carrier 304.

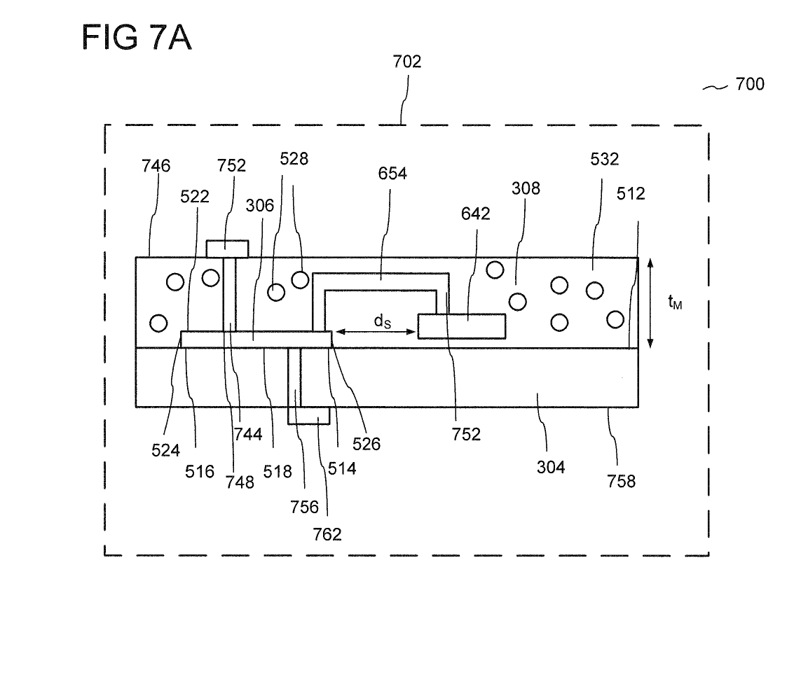

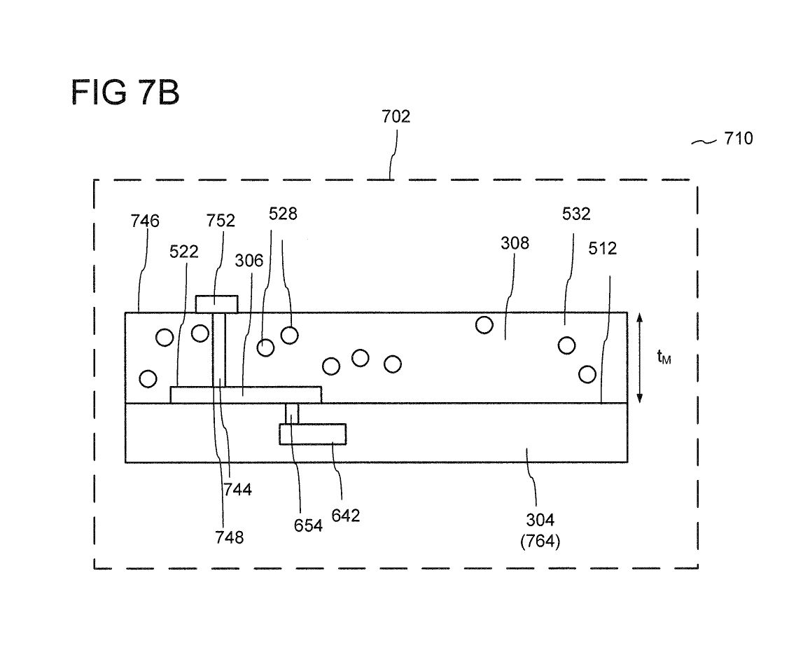

FIG. 7A shows chip arrangement 702 according to an embodiment. Chip arrangement 702 may include one or more or all the features already described with respect to chip arrangement 502. Furthermore, chip arrangement 702 may include one or more or all the basic functionalities of the features already described with respect to chip arrangement 502.

Method 500 may be modified, e.g. one or more processes may be removed and/or added to method 500, to produce chip arrangement 702.

In comparison to chip arrangement 502, chip arrangement 702 may optionally further include electronic component 642, wherein electronic component 642 may be embedded and/or surrounded by at least one of carrier 304 and ceramic layer 308. Electronic component 642 may include at least one of the electronic components already described with respect to FIG. 6, and may be electrically connected to chip 306 as part of circuit 600 as described and shown with respect to FIG. 6. Electronic component 642 may be electrically insulated from chip 306 as electronic component 642 may be embedded in at least one of carrier 304 and ceramic layer 308. Chip 306 and electronic components 642 may be embedded and surrounded by carrier 304 and ceramic layer 308 in parallel. Electronic component 642 may include a passive device. The passive device may include at least one passive device from the group of passive devices, the group consisting of: a capacitor, and an inductor.

According to an embodiment, electronic component 642 may be disposed adjacent to chip 306. Electronic component 642 and chip 306 may be separated by a separation distance d_{S} over carrier 304. Separation distance d_{S} may range from about 10 μm to about 10 mm, e.g. from about 50 μm to about 5 mm, e.g. from about 100 μm to about 1 mm. Electronic component 642 may be disposed over carrier 304 and/or within a further cavity formed within carrier 304. Electronic component 642 may be surrounded by at least one of carrier 304 and ceramic layer 308.

Ceramic layer 308, as already described with respect to method 500, may be formed over chip 306, wherein ceramic layer 308 may at least partially surround chip 306. Ceramic layer 308 may be formed over electronic component 642, wherein ceramic layer 308 may at least partially surround electronic component 642. Ceramic layer 308 and/or carrier 304 may be formed between chip 306 and electronic component 642, for example, between a chip lateral side 526 and electronic component 642.

According to another embodiment, electronic component 642 and chip 304 may be embedded separately in ceramic materials. As shown in FIG. 7B, chip 304 may be embedded in further ceramic material 764, wherein further ceramic material 764 may fully surround and/or be formed directly on electronic component 642. Further ceramic material may be sintered so as to be joined to at least one of carrier 304 and ceramic layer 308. This may produce a stacked arrangement, wherein electronic component 642 may be arranged above or below chip 304. As shown in FIG. 7B, further ceramic material 764 may include the same material as that used for carrier 304. Furthermore, further ceramic material 764 may further be used as an embedding material for chip 306 as well. For example, further ceramic material may include carrier 304 for embedding chip 306.

According to various embodiments, e.g. FIG. 7A and FIG. 7B, one or more through-holes 744 may be formed through ceramic layer 308, the one or more through-holes 744 extending between ceramic material top side 746 and chip top side 522. One or more through-holes 744 may extend between ceramic material top side 746 and one or more contact pads 748 formed over chip top side 522. One or more contact pads 748 may include at least one of a source/drain contact and/or a gate contact.

One or more through-holes 744 may be filled with one or more electrically conductive portions 752, wherein one or more electrically conductive portions 752 may include an electrically conductive material. One or more electrically conductive portions 752 may be in electrical connection with chip 306, wherein ceramic layer 308 may at least partially surround one or more electrically conductive portions 752. At least part of one or more electrically conductive portions 752 may be formed over ceramic layer 308, e.g. over ceramic material top side 746. One or more electrically conductive portions 752 may extend between ceramic material top side 746 and one or more contact pads 748 formed over chip top side 522. Ceramic material top side 746 may face the same direction as chip top side 522. It may be understood that ceramic layer 308 may be formed substantially over chip top side 522, for example ceramic layer 308 may be formed over the entire chip top side 522, except for wherein one or more electrically conductive portions 752 electrically contact chip top side 522. At least part of one or more electrically conductive portions 752 formed over ceramic material top side 746 may form part of a electrically conductive redistribution layer for the one or more contact pads 748 formed over chip top side 522. At least part of one or more electrically conductive portions 752 formed over ceramic material top side 746 may be connected to carrier 304. For example, one or more electrically conductive portions 752 may be electrically connected to carrier 304 if carrier 304 included an electrically conductive lead frame.

Electronic component 642 may be electrically connected to chip 306 by one or more electrical interconnects 654 formed through at least one of carrier 304 and ceramic layer 308. Electronic component 642 may be, except for one or more electrically interconnects 654, electrically insulated by at least one of carrier 304 and ceramic layer 308 from chip 306. At least one ceramic layer 308 and carrier 304 may fully surround one or more electrical interconnects 654.

According to various other embodiments, carrier 304 may include a ceramic material, and one or more further through-holes 756 may be formed through carrier 304, the one or more further through-holes 756 extending between carrier bottom side 758 and chip bottom side 516. One or more further through-holes 756 may extend between carrier bottom side 758 and at least one contact pad 514 formed over chip bottom side 516, e.g. if chip 306 includes a power semiconductor chip.

One or more further through-holes 756 may be filled with one or more electrically conductive portions 762, wherein one or more further electrically conductive portions 762 may include an electrically conductive material. One or more further electrically conductive portions 762 may be in electrical connection with chip 306, wherein carrier 304 may at least partially surround one or more electrically conductive portions 762. At least part of one or more further electrically conductive portions 762 may be formed over carrier 304, e.g. over carrier bottom side 758. One or more further electrically conductive portions 762 may extend between carrier bottom side 758 and at least one contact pad 514 formed over chip bottom side 516. At least part of one or more further electrically conductive portions 762 formed over carrier 304 may form part of a electrically conductive redistribution layer for the at least one contact pad 514 formed over chip bottom side 516.

According to various embodiments, chip arrangements 502,702 may include a chip package including carrier 304; power semiconductor chip 306 disposed over and electrically contacted to carrier 304; an encapsulation material 308 formed over and at least partially surrounding the power semiconductor chip 306, wherein the encapsulation material 308 includes a plurality of ceramic structures 528 embedded in a filler material 532.

According to various embodiments, chip arrangements 502,702 may include carrier 304; chip 306 disposed over and electrically contacted to carrier 304; electronic component 642 disposed over and electrically insulated from carrier 304; an encapsulation material formed over and between chip 306 and electronic component 642; wherein encapsulation material includes a ceramic layer 308.

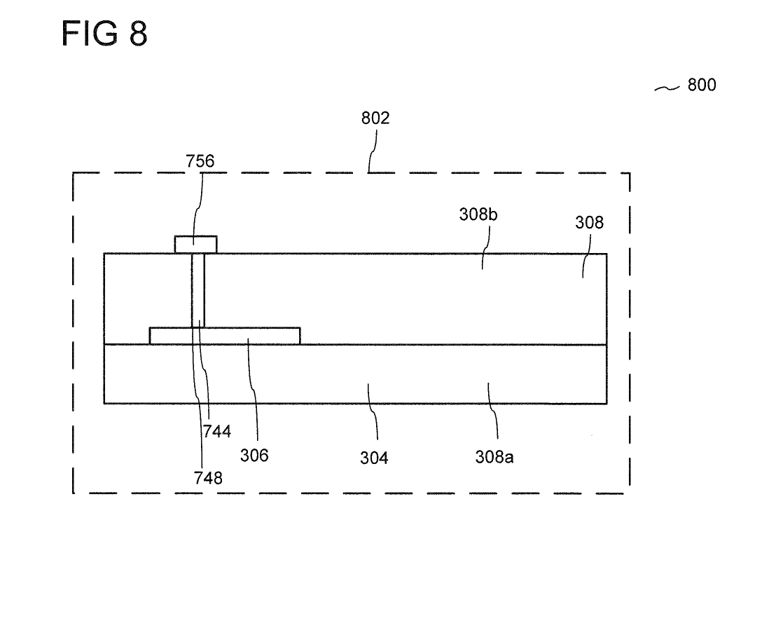

FIG. 8 shows chip arrangement 802 according to an embodiment.

Chip arrangement 802 may include one or more or all the features already described with respect to chip arrangements 502, 702. Furthermore, chip arrangement 702 may include one or more or all the basic functionalities of the features already described with respect to chip arrangements 502, 702.

Chip arrangement 802 may include chip 304; ceramic encapsulation material 308; wherein a portion of ceramic encapsulation material 308a may be disposed over chip bottom side 516 and wherein further portion of the ceramic encapsulation material 308b may be formed over chip top side 522; at least one through-hole 744 formed through ceramic encapsulation material 308; and electrically conductive material 752 formed within at least one through-hole 744, wherein electrically conductive material 752 may be electrically connected to at least one of the chip bottom side 516 and chip top side 522.

Various embodiments provide a chip arrangement, including: a carrier; a chip disposed over the carrier; a ceramic layer formed over the chip and on at least a portion of the carrier; wherein the chip is surrounded by the carrier and the ceramic layer.

According to an embodiment, the carrier includes an electrically conductive material, the electrically conductive material including at least one material from the following group of materials, the group consisting of: copper, aluminum, silver, tin, gold, zinc, nickel.

According to an embodiment, the carrier includes a ceramic material.

According to an embodiment, at least one of the carrier and the ceramic layer includes at least one material from the following group of materials, the group of materials consisting of: calcium oxide, aluminum oxide, silicon oxide, aluminum nitride, and zirconium oxide, boron nitride, a metal oxide, a metal nitride.

According to an embodiment, at least one of the carrier and the ceramic layer includes one or more structures, the one or more structures including: particles, nanoparticles, microparticles, fibers, microfibers, nanofibers, nanostructures, microstructures.

According to an embodiment, at least one of the carrier and the ceramic layer each includes a composite material including an embedding portion and a filler portion; wherein the embedding portion includes at least one material from the following group of materials, the group of materials consisting of epoxy, polyimide, duroplast, polyacrylate; and wherein the filler portion includes one or more structures including at least one material from the following group of materials, the group of materials consisting of: calcium oxide, aluminum oxide, silicon oxide, aluminum nitride, and zirconium oxide, boron nitride, a metal oxide, a metal nitride.

According to an embodiment, the carrier and the ceramic layer include the same or different materials.

According to an embodiment, the carrier surrounds a chip bottom side and the ceramic layer surrounds a chip top side and one or more lateral sides of the chip.

According to an embodiment, the carrier includes a cavity formed in the carrier; and the chip is disposed within the cavity.

According to an embodiment, the carrier surrounds a chip bottom side and one or more lateral sides of the chip; and the ceramic layer surrounds a chip top side.

According to an embodiment, the chip arrangement further includes one or more through holes formed through at least one of the carrier and the ceramic layer; and electrically conductive material formed within the one or more through-holes, wherein the electrically conductive material is electrically connected to the chip.

According to an embodiment, the electrically conductive material includes at least one from the following group of materials, the group of materials consisting of: copper, aluminum, silver, tin, gold, zinc, nickel.

According to an embodiment, at least a portion of the electrically conductive material is formed over the at least one of the carrier and the ceramic layer.

According to an embodiment, the chip includes a power semiconductor chip.

According to an embodiment, the power semiconductor chip includes at least one power semiconductor device from the group of power semiconductor devices, the group consisting of: a power transistor, a power MOS transistor, a power bipolar transistor, a power field effect transistor, a power insulated gate bipolar transistor, a thyristor, a MOS controlled thyristors, a silicon controlled rectifier, a power schottky diode, a silicon carbide diode, a gallium nitride device.

According to an embodiment, the chip includes a semiconductor logic chip.

According to an embodiment, the semiconductor logic chip includes at least one semiconductor logic device from the group of semiconductor logic devices, the group consisting of: an application specific integrated circuit ASIC, a driver, a controller, a sensor.

According to an embodiment, the chip arrangement further includes an electronic component surrounded by at least one of the carrier and the ceramic layer.

According to an embodiment, the electronic component includes a passive electronic device, the passive electronic device including at least one from the following group of devices, the group consisting of: an inductor, a capacitor, a resistor.

According to an embodiment, the chip is electrically connected to the electronic component by one or more electrically interconnects formed through at least one of the carrier and the ceramic layer.

Various embodiments provide a chip arrangement, including: a chip; a ceramic encapsulation material; wherein a portion of the ceramic encapsulation material is disposed over a chip bottom side and wherein a further portion of the ceramic encapsulation material is formed over the chip top side; at least one through-hole formed through the ceramic encapsulation material; and electrically conductive material formed within the at least one through-hole, wherein the electrically conductive material is electrically connected to at least one of the chip bottom side or the chip top side.

Various embodiments provide a method for forming a chip arrangement, the method including: disposing a chip over a carrier and electrically contacting the chip to the carrier; and forming a ceramic layer over the chip and on at least a portion of the carrier such that the chip is surrounded by the carrier and the ceramic layer.

According to an embodiment, the method further includes subsequently performing a sintering process on at least one of the carrier and the ceramic layer.

Various embodiments provide a method for forming a chip arrangement, the method including: disposing a ceramic encapsulation material over a chip bottom side and over a chip top side; forming at least one through-hole through the ceramic encapsulation material; and forming electrically conductive material within the at least one through-hole, wherein the electrically conductive material is electrically connected to at least one of the chip bottom side or the chip top side.

According to an embodiment, the method further includes disposing the ceramic encapsulation material over one or more chip lateral sides wherein the ceramic encapsulation material surrounds the chip; and subsequently performing a sintering process on at least one of the carrier and the ceramic layer.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. A chip arrangement, comprising:
a carrier;
a chip disposed over the carrier;
a ceramic layer formed over the chip and on at least a portion of the carrier;
wherein the chip is surrounded by the carrier and the ceramic layer.

2. The chip arrangement according to claim 1,
wherein the carrier comprises an electrically conductive material, the electrically conductive material comprising at least one material from the following group of materials, the group consisting of: copper, aluminum, silver, tin, gold, zinc, nickel.

3. The chip arrangement according to claim 1,
wherein the carrier comprises a ceramic material.

4. The chip arrangement according to claim 1,
wherein at least one of the carrier and the ceramic layer comprises at least one material from the following group of materials, the group of materials consisting of: calcium oxide, aluminum oxide, silicon oxide, aluminum nitride, and zirconium oxide, boron nitride, a metal oxide, a metal nitride.

5. The chip arrangement according to claim 1,
wherein at least one of the carrier and the ceramic layer comprises one or more structures, the one or more structures comprising: particles, nanoparticles, microparticles, fibers, microfibers, nanofibers, nanostructures, microstructures.

6. The chip arrangement according to claim 1,
wherein at least one of the carrier and the ceramic layer each comprises a composite material comprising an embedding portion and a filler portion;
wherein the embedding portion comprises at least one material from the following group of materials, the group of materials consisting of: epoxy, polyimide, duroplast, polyacrylate; and
wherein the filler portion comprises one or more structures comprising at least one material from the following group of materials, the group of materials consisting of: calcium oxide, aluminum oxide, silicon oxide, aluminum nitride, and zirconium oxide, boron nitride, a metal oxide, a metal nitride.

7. The chip arrangement according to claim 1,
wherein the carrier and the ceramic layer comprise the same or different materials.

8. The chip arrangement according to claim 1,
wherein the carrier surrounds a chip bottom side and
wherein the ceramic layer surrounds a chip top side and one or more lateral sides of the chip.

9. The chip arrangement according to claim 1,
wherein the carrier comprises a cavity formed in the carrier; and
wherein the chip is disposed within the cavity.

10. The chip arrangement according to claim 9,
wherein the carrier surrounds a chip bottom side and one or more lateral sides of the chip; and
wherein the ceramic layer surrounds a chip top side.

11. The chip arrangement according to claim 1, further comprising
one or more through holes formed through at least one of the carrier and the ceramic layer; and
electrically conductive material formed within the one or more through-holes, wherein the electrically conductive material is electrically connected to the chip.

12. The chip arrangement according to claim 11,
wherein the electrically conductive material comprises at least one from the following group of materials, the group of materials consisting of: copper, aluminum, silver, tin, gold, zinc, nickel.

13. The chip arrangement according to claim 11,
wherein at least a portion of the electrically conductive material is formed over the at least one of the carrier and the ceramic layer.

14. The chip arrangement according to claim 1,
wherein the chip comprises a power semiconductor chip.

15. The chip arrangement according to claim 14,
wherein the power semiconductor chip comprises at least one power semiconductor device from the group of power semiconductor devices, the group consisting of: a power transistor, a power MOS transistor, a power bipolar transistor, a power field effect transistor, a power insulated gate bipolar transistor, a thyristor, a MOS controlled thyristors, a silicon controlled rectifier, a power schottky diode, a silicon carbide diode, a gallium nitride device.

16. The chip arrangement according to claim 1,
wherein the chip comprises a semiconductor logic chip.

17. The chip arrangement according to claim 16,
wherein the semiconductor logic chip comprises at least one semiconductor logic device from the group of semiconductor logic devices, the group consisting of: an application specific integrated circuit ASIC, a driver, a controller, a sensor.

18. The chip arrangement according to claim 1, further comprising
an electronic component surrounded by at least one of the carrier and the ceramic layer.

19. The chip arrangement according to claim 8,
wherein the electronic component comprises a passive electronic device, the passive electronic device comprising at least one from the following group of devices, the group consisting of: an inductor, a capacitor, a resistor.

20. The chip arrangement according to claim 18,
wherein the chip is electrically connected to the electronic component by one or more electrically interconnects formed through at least one of the carrier and the ceramic layer.

21. A chip arrangement, comprising:
a chip;
a ceramic encapsulation material;
wherein a portion of the ceramic encapsulation material is disposed over a chip bottom side and wherein a further portion of the ceramic encapsulation material is formed over the chip top side;
at least one through-hole formed through the ceramic encapsulation material; and
electrically conductive material formed within the at least one through-hole, wherein the electrically conductive material is electrically connected to at least one of the chip bottom side or the chip top side.

22. A method for forming a chip arrangement, the method comprising:
disposing a chip over a carrier and electrically contacting the chip to the carrier;
forming a ceramic layer over the chip and on at least a portion of the carrier such that the chip is surrounded by the carrier and the ceramic layer.

23. The method according to claim 22, further comprising
subsequently performing a sintering process on at least one of the carrier and the ceramic layer.

24. A method for forming a chip arrangement, the method comprising:
disposing a ceramic encapsulation material over a chip bottom side and over a chip top side;
forming at least one through-hole through the ceramic encapsulation material; and
forming electrically conductive material within the at least one through-hole, wherein the electrically conductive material is electrically connected to at least one of the chip bottom side and the chip top side.

25. The method according to claim 24, further comprising
disposing the ceramic encapsulation material over one or more chip lateral sides wherein the ceramic encapsulation material surrounds the chip; and
subsequently performing a sintering process on at least one of the carrier and the ceramic layer.
